(19) United States
(12) Patent Application Publication
(10) Pub. No.: US 2026/0255889 A1
(43) Pub. Date: Aug. 27, 2026

(54) QUANTUM CIRCUIT APPARATUS AND CONTROL METHOD

(71) Applicant: NEC Corporation, Tokyo (JP)

(72) Inventor: Yohei KAWAKAMI, Tokyo (JP)

(73) Assignee: NEC Corporation, Tokyo (JP)

(21) Appl. No.: 19/542,803

(22) Filed: Feb. 18, 2026

(30) Foreign Application Priority Data
Feb. 27, 2025 (JP) 2025-030267

(51) Int. Cl. H10N 99/00; G06N 10/40; H10N 60/12

(52) U.S. Cl. CPC H10N 99/05; G06N 10/40; H10N 60/12

(57) ABSTRACT

A quantum circuit apparatus includes N qubits, where N is a predetermined integer of 3 or more, and a coupler, the N qubits configured to be coupled through the coupler via a many-body interaction, wherein at least one qubit out of the N qubits is configured to have a sign of a parameter representing nonlinearity of the at least one qubit different from a sign of a parameter representing nonlinearity of the coupler and/or a sign of a parameter representing nonlinearity of at least one other of the N qubits.

### FIELD

### Cross Reference to Related Applications

The present application is based upon and claims the benefit of the priority of Japanese patent application No. 2025-030267, filed on Feb. 27, 2025, the disclosure of which is incorporated herein in its entirety by reference thereto.

The present disclosure relates to a quantum circuit apparatus and control method.

### BACKGROUND

In an LHZ (Lechner, Hauke, Zoller) scheme which is one approach to quantum annealing for solving combinatorial optimization problems, an interaction among quantum bits (qubits) such as a four-body interaction (Non-Patent Literature (NPL) 1) is required. Non-Patent Literature 2 discloses as a physical implementation of the LHZ scheme, a network illustrated in FIG. 1, which utilizes a four-body interaction among four qubits via a coupler. FIG. 1 is based on a of FIG. 4 in Non-Patent Literature 2. In the example illustrated in FIG. 1, a Josephson Parametric Oscillator (JPO) is used as a qubit, and a coupler is provided with a Josephson junction (JJ).
NPL 1: Lechner, Hauke, Zoller, “A quantum annealing architecture with all-to-all connectivity from local interactions”, Science Advances 23 Oct. 2015 Vol 1, Issue 9: DOI: 10.1126/sciadv.1500838
NPL 2: Shruti Puri, Christian Kraglund Andersen, Arne L. Grimsmo, Alexandre Blais, “Quantum annealing with a network of all-to-all connected, two-photon driven Kerr nonlinear oscillators”, Nature Commun 8, 15785 (2017)

### SUMMARY

A qubit is a resonator with nonlinearity. The circuit in FIG. 1 exhibits two types of cross-Kerr interactions: a cross-Kerr interaction between qubits and a cross-Kerr interaction between a qubit and a coupler. The cross-Kerr interaction is known to produce an adverse effect on a circuit's operation, such as alteration of a resonance frequency of a qubit.

One of objects of the present disclosure is to provide a quantum circuit apparatus and a control method, each enabling to solve the above-described issue.

According to one aspect of a quantum circuit apparatus of the present disclosure, a quantum circuit apparatus includes N qubits, where N is a predetermined integer of 3 or greater; and a coupler, the N qubits configured to be coupled through the coupler via a many-body interaction, wherein at least one qubit of the N qubits is configured to have a sign of a parameter representing nonlinearity of the at least one qubit different from a sign of a parameter representing nonlinearity of the coupler and/or a sign of a parameter representing nonlinearity of at least one other of the N qubits.

According to one aspect of the present disclosure, there is provided a control method of a quantum circuit that includes N qubits, where N is a predetermined integer of 3 or greater; and a coupler, the N qubits configured to be coupled through the coupler via a many-body interaction, wherein the method includes configuring at least one qubit of the N qubits to have a sign of a parameter representing nonlinearity of the at least one qubit different from a sign of a parameter representing nonlinearity of the coupler and/or a sign of a parameter representing nonlinearity of at least one other of the N qubits.

According the present disclosure, there is provided an apparatus and a method enabling to suppress or cancel out a cross-Kerr interaction between a qubit and a coupler, and/or a cross-Kerr interaction between qubits.

### BRIEF DESCRIPTION OF THE DRAWINGS

FIG. 1 is a diagram illustrating an example of the disclosure of Non-Patent Literature 2.

FIG. 2 is a diagram illustrating at least an example of embodiments of the present disclosure.

FIGS. 3A and 3B are diagrams each illustrating at least an example of embodiments of the present disclosure, respectively.

FIG. 4 is a diagram illustrating at least an example of embodiments of the present disclosure.

FIG. 5 is a diagram illustrating at least an example of embodiments of the present disclosure.

FIGS. 6A and 6B are diagrams each illustrating at least an example of embodiments of the present disclosure, respectively.

FIGS. 7A, 7B, and 7C are diagrams each illustrating at least an example of embodiments of the present disclosure, respectively.

FIG. 8 is a diagram illustrating at least an example of embodiments of the present disclosure.

FIG. 9 is a diagram illustrating at least an example of embodiments of the present disclosure.

FIG. 10 is a diagram illustrating at least an example of embodiments of the present disclosure.

FIG. 11 is a diagram illustrating at least an example of embodiments of the present disclosure (a diagram illustrating a quantum annealing machine).

### DESCRIPTION OF EMBODIMENTS

The following describes embodiments of the present disclosure. The present disclosure presents a quantum circuit apparatus that is enabled to suppress or cancel out a cross-Kerr interaction using a combination of a qubit(s) and a coupler having different signs (polarities) in nonlinearity thereof.

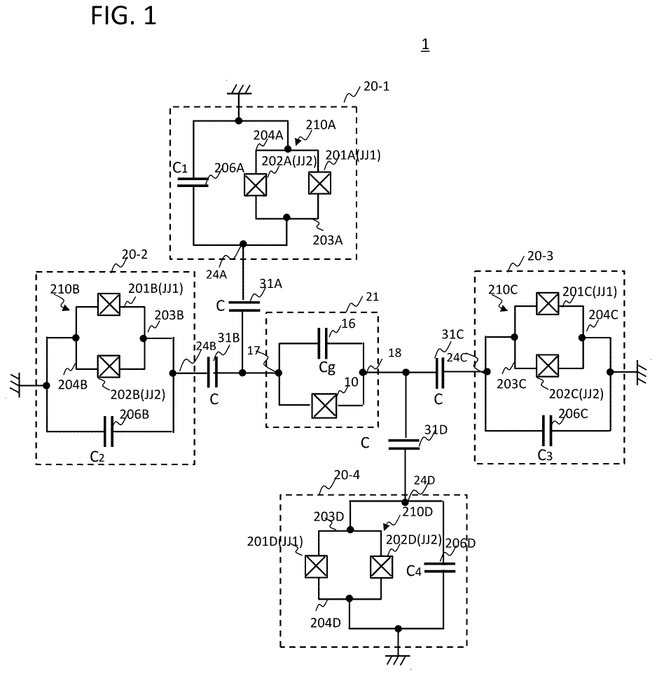

First, an analysis of a configuration illustrated in FIG. 1 is provided to find an issue(s) thereof. Referring to FIG. 1, a quantum circuit apparatus 1 includes four qubits 20-1 to 20-4 and a coupler 21. More specifically, the first qubit 20-1 includes a superconducting member 203A that is set in a superconducting state at an extremely low (cryogenic) temperature, a Josephson junction 201A, a superconducting member 204A that is set in a superconducting state at an extremely low (cryogenic) temperature, and a Josephson junction 202A, which together form a loop constituting a SQUID 210A. The superconducting member 203A is connected to an electrode 24A, the superconducting member 204A is connected to ground. The first qubit 20-1 includes a capacitor 206A (shunt capacitor) connected in parallel with the SQUID 210A between the electrode 24A and ground. In operation, a magnetic flux penetrating the SQUID 210A is generated by a current provided by an a n unillustrated signal source to flow through unillustrated inductor (magnetic field generation part). A resonance angular frequency ω₁ of the first qubit 20-1 is varied according to the magnetic flux penetrating the SQUID 210A. For the second through fourth qubits 20-2 to 20-4, respectively, superconducting members 203B to 203D corresponding to the superconducting member 203A of the first qubit 20-1, Josephson junctions 201B to 201D corresponding to Josephson junction 201A of the first qubit 20-1, superconducting members 204B to 204D corresponding to the superconducting member 204A of the first qubit 20-1, Josephson junctions 202B to 202D corresponding to the Josephson junction 202A of the first qubit 20-1, SQUIDs 210B to 210D corresponding to the SQUID 210A of the first qubit 20-1, and capacitors 206B to 206D corresponding to the capacitor 206A of the first qubit 20-1 are provided. In operation, a magnetic flux penetrating each of the SQUIDs 210B to 210D is generated by a current flowing from an unillustrated signal source through unillustrated inductor an (magnetic field generation part) to ground. Resonant angular frequencies ω₂ to ω₄ of the second to fourth qubits 20-2 to 20-4 are varied according to the magnetic fluxes penetrating the SQUIDs 210B to 210D, respectively.

The coupler 21 includes a Josephson junction 10 and a capacitor 16 that are connected in parallel between a first electrode (first node) 17 and a second electrode (second node) 18. The first electrode 17 is coupled to the first qubit 20-1 and the second qubit 20-2 via coupling capacitors 31A and 31B (capacitive coupling), respectively, and the second electrode 18 is connected to the third qubit 20-3 and the fourth qubit 20-4 via coupling capacitors 31C and 31D (capacitive coupling), respectively. Note that in the following, when there is no need to discriminate a qubit, a branch number of a reference sign of the qubit is omitted, and a qubit is designated as a qubit 20. The same applies to other elements.

In the circuit illustrated in FIG. 1, there are two types of Cross-Kerr interactions (abbreviated as “CKI”): one acting between qubits 20 (referred to as “QQ-CKI”) and one acting between a qubit 20 and a coupler 21 (referred to as “QC-CKI”).

QQ-CKI is proportional to a sum of nonlinearity of two qubits 20. QQ-CKI has 4!/2!=4×3/2=6 combinations (types), which are proportional to:

$$( {K}_{1} + {K}_{2} ) ;$$

$$( {K}_{1} + {K}_{3} ) ;$$

$$( {K}_{1} + {K}_{4} ) ;$$

$$( {K}_{2} + {K}_{3} ) ;$$

$$( {K}_{2} + {K}_{4} ) ;$$

$$and$$

$$( {K}_{3} + {K}_{4} ) ,$$

where, Kᵢ (i=1, 2, 3, 4) is a parameter (or coefficient) representing nonlinearity (Kerr nonlinearity) of the i-th qubit 20-i. Kᵢ is also referred to as a nonlinear parameter of the i-th qubit 20-i.

Kᵢ may be corresponded to a Kerr nonlinearity Kᵢ in a Hamiltonian Hi of the i-th qubit (JPO) 20-i (i=1, 2, 3, 4) in FIG. 1, expressed as the following equation (1).

$$Hi = {Δ a}_{i}^{+} {a}_{i} - {K}_{i} ( {a}_{i}^{{+}^{2}} {{a}_{i}}^{2} ) + {E}_{p} ( {a}_{i}^{{+}^{2}} {{a}_{i}}^{2} )$$

(1)

In equation (1),
Δ is the difference between a resonance angular frequency ω_{c} of the coupler 21 and half an angular frequency ωₚ of the i-th pump signal:

$$Δ = {ω}_{c} - ( \frac{1}{2} ) {ω}_{p} \qquad ( 2 )$$

Ep is a strength of the two-photon drive (pump term).

aᵢ⁺ and aᵢ are creation and annihilation operators for bosons (photons) in the i-th qubit 20-i.

QC-CKI is proportional to the sum of the nonlinearity of the qubit 20 and the nonlinearity of the coupler 21. QC-CKI has four types corresponding to the first to fourth qubits 20-1 to 20-4, each proportional to:

$$( {K}_{1} + {K}_{g} ) ;$$

$$( {K}_{2} + {K}_{g} ) ;$$

$$( {K}_{3} + {K}_{g} ) ;$$

$$and$$

$$( {K}_{4} + {K}_{g} ) ,$$

where K_{g} is a parameter (Kerr coefficient) representing the nonlinearity (Kerr nonlinearity) of the coupler 21. K_{g} is also referred to as the nonlinear parameter of the coupler 21.

As described before, a cross-Kerr interaction is known to produce adverse effect on a circuit's operation, such as by altering the resonance frequency of qubit 20.

The above issue is one example, but according to the present disclosure, it is possible to suppress contribution of nonlinearity of a qubit(s) 20, in a many-body interaction among qubits 20 in various cases, not limited to the above.

For the circuit illustrated in FIG. 1, angular frequencies of respective pump signals are configured as follows, as a condition for the first to fourth qubits 20-1 to 20-4 (JPO1 to JPO4) to be coupled via a four-body interaction (NPL 2).

$${ω}_{p , 1} + {ω}_{p , 2} = {ω}_{P , 3} + {ω}_{p , 4} \qquad ( 3 )$$

where ω_{p,i} (i=1, 2, 3, 4) is an angular frequency of a pump signal supplied to an i-th qubit 20-i. An alternating signal with an angular frequency approximately twice a resonance angular frequency ωᵢ of the i-th qubit 20-i is supplied as the pump signal to the i-th qubit 20-i.

Regarding the circuit illustrated in FIG. 1, in a Hamiltonian in a rotating frame, i.e., a rotating wave approximation (RWA), a coupling term for a four-body interaction among the four qubits 20-1 to 20-4 via the coupler 21 may be given by the following equation (2) (e.g., NPL 2).

$${g}^{( 4 )} ( {a}_{1}^{†} {a}_{2}^{†} {a}_{3} {a}_{4} + {a}_{4}^{†} {a}_{3}^{†} {a}_{2} {a}_{1} ) \qquad ( 4 )$$

where aᵢ and aᵢ⁺ (i=1, 2, 3, 4) represent annihilation and creation operators for a boson in i-th qubit, respectively.

In equation (4), a strength (coupling coefficient) g⁽⁴⁾ of the four-body interaction is given by:

$${g}^{( 4 )} = {K}_{g} \frac{{g}_{1} {g}_{2} {g}_{3} {g}_{4}}{{Δ}_{1} {Δ}_{2} {Δ}_{3} {Δ}_{4}} \qquad ( 5 )$$

The strength (coupling coefficient) g⁽⁴⁾ depends on nonlinearity of the Josephson junction 10 in the coupler 21 and a difference (detuning) between the resonant frequencies of each of the qubits 20-1 to 20-4 and the coupler 21.

In equation (5),
K_{g} is a parameter (Kerr coefficient) representing nonlinearity of the coupler 21. K_{g} is also referred to as a nonlinear parameter of the coupler 21.

Δᵢ (i=1, 2, 3, 4) is a difference (detuning) between the resonance angular frequency ω_{c} of the coupler 21 and the resonance angular frequency ωᵢ of the i-th qubit 20-i (=ω_{c}−ωᵢ).

gᵢ (i=1, 2, 3, 4) is a coupling strength between the i-th qubit 20-i and the coupler 21.

From equation (5), by configuring the detuning Δᵢ as small as possible within a range:

$$\frac{{g}_{i}}{{Δ}_{i}} < 1 ( i = 1 , 2 , 3 , 4 ) \qquad ( 6 )$$

the four-body interaction coupling coefficient g⁽⁴⁾ can be made large, thereby strengthening the four-body interaction. Therefore, the resonance angular frequency ωᵢ (i=1, 2, 3, 4) of the i-th qubit 20-i and the resonance angular frequency ω_{c} of the coupler 21 may be set to be sufficiently close.

In equation (5), approximating each gᵢ/Δᵢ (i=1, 2, 3, 4) with g/Δ, g⁽⁴⁾ corresponds to the nonlinear parameter K_{g} of the coupler 21 multiplied by the fourth power term of g/Δ: (g/Δ)⁴.

From equation (5), increasing the nonlinear parameter K_{g} of the coupler 21 results in a larger coupling coefficient g⁽⁴⁾ for the four-body interaction. However, the nonlinear parameter K_{g} of the coupler 21 is multiplied by (g/Δ)⁴, which is less than 1. Therefore, the coupling coefficient g⁽⁴⁾ for the four-body interaction can only be a small value in principle. That is, in the circuit of FIG. 1, it is basically difficult to make the coupling coefficient g⁽⁴⁾ for the four-body interaction large.

The present disclosure, in addition to suppressing the cross-Kerr interaction described above, may also contribute to increasing the strength of the four-body interaction by combining the coefficient h⁽⁴⁾, which indicates the strength of the four-body interaction due to the nonlinearity (Kerr nonlinearity) of the qubits 20 and the coupling coefficient g⁽⁴⁾ of the four-body interaction through the coupler 21.

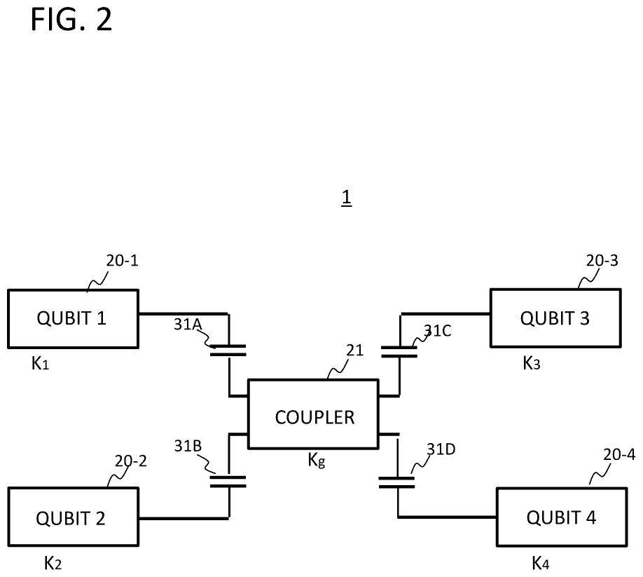

FIG. 2 is a schematic diagram illustrating a n example embodiment of the present disclosure. Referring to FIG. 2, the first to fourth qubits 20-1 to 20-4 are each connected (capacitively coupled) to a coupler 21 via coupling capacitors 31A to 31D, respectively, and are configured to be coupled via a four-body interaction.

In FIG. 2, for example,
the first to fourth qubits 20-1 to 20-4 are configured to have the nonlinear parameters K₁ to K₄ which are set to the same value K, and
the coupler 21 is configured to have the nonlinear parameter K_{g} of the coupler 21 which is set to −K.

In this case, the QC-CKI proportional to the sum of the nonlinearities of the qubits 20 and coupler 21: (K₁+K_{g}), (K₂+K_{g}), (K₃+K_{g}), (K₄+K_{g}) will all be zero.

In FIG. 2, as a not limiting example, the first to fourth qubits 20-1 to 20-4 may be configured using JPOs with SQUIDs, and the coupler 21 may be configured using a JPO containing a SNAIL (Superconducting Nonlinear Asymmetric Inductive eLement).

Though not limited thereto, the nonlinear parameters K₁ to K₄ of the first to fourth qubits 20-1 to 20-4 may be set to positive values, while the nonlinear parameter K_{g} of the coupler 21 may be set to a negative value, for example. Alternatively, the nonlinear parameters K₁ to K₄ of the first to fourth qubits 20-1 to 20-4 may be set to negative values, while the nonlinear parameter K_{g} of the coupler 21 may be set to a positive value. When thus configured, it is possible to suppress an influence of the cross-Kerr interaction (QC-CKI) between the qubits 20 and the coupler 21, which has an effect on the four-body interaction.

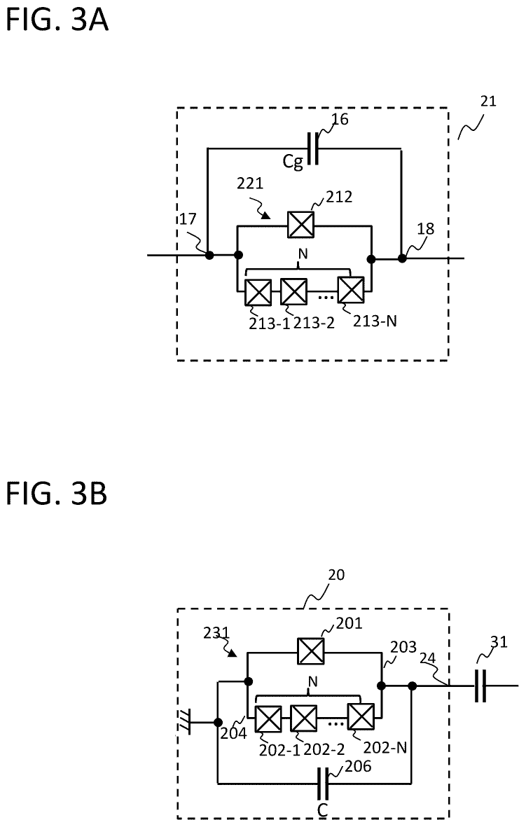

In FIG. 2, the coupler 21 may be configured as a JPO including a SNAIL 221, as illustrated in FIG. 3A. Referring to FIG. 3A, the SNAIL 221 may be configured with such an arrangement that a Josephson junction 212 and N Josephson junctions 213-1 to 213-N (N≥2) connected in series are connected in parallel between a first electrode (first node) 17 and a second electrode (second node) 18 (the Josephson junction 212 and Josephson junctions 213-1 to 213-N form a loop). A Josephson energy E_{J2} of the Josephson junction 212 is a times (0<α<1) a Josephson energy E_{Jg} of each Josephson junction 213-1 to 213-N. Since the Josephson energy is proportional to a critical current, the critical current of the Josephson junction 212 is α times (0<α<1) a critical current I_{cg} of each Josephson junction 213-1 to 213-N. The critical current value of the Josephson junction is proportional to a junction size (junction area) of the Josephson junction. Therefore, the junction size of Josephson junction 212 is smaller than the junction size of each Josephson junctions 213-1 to 213-N, and the junction size of the Josephson junction 212 is a times (0<α<1) the junction size of each of the Josephson junctions 213-1 to 213-N. Connecting the Josephson junctions 213-1 to 213-N in series reduces nonlinearity. Furthermore, a qubit 20 may also be configured as a SNAIL structure, as illustrated in FIG. 3 B.

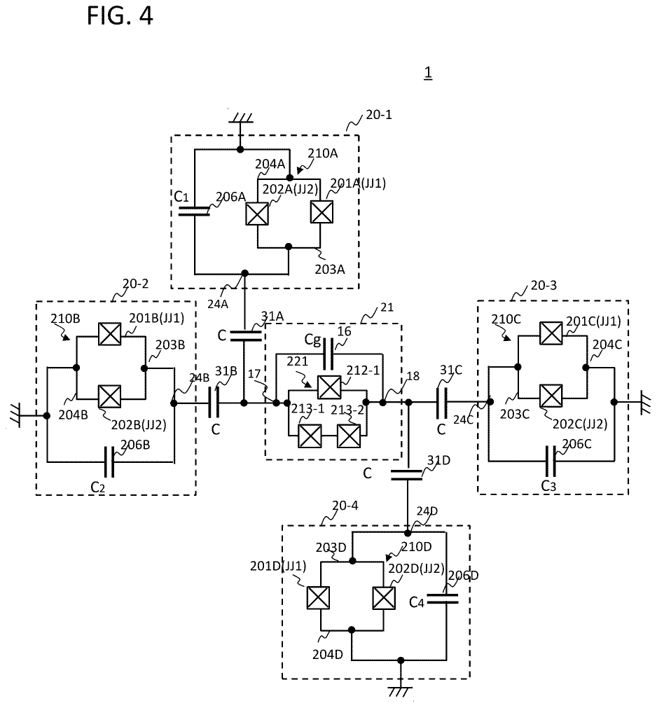

FIG. 4 illustrates an example circuit configuration of FIG. 2. Referring to FIG. 4, in the quantum circuit apparatus 1, the first qubit 20-1 includes a SQUID 210A wherein a superconducting member 203A, a Josephson junction 201A, a superconducting member 204A and a Josephson junction 202A are arranged to form a loop. The superconducting member 203A is connected to an electrode 24A, and the superconducting member 204A is connected to ground. A capacitor 206A (shunt capacitor) is connected in parallel with the SQUID 210A between the electrode 24A and ground. Current is flown through an unillustrated inductor to generate a magnetic flux that penetrates the SQUID 210A. By varying the magnetic flux, a resonance angular frequency ω₁ of the first qubit 20-1 is varied. The second to fourth qubits 20-2 to 20-4, include respectively, superconducting members 203B to 203D corresponding to the superconducting member 203A of the first qubit 20-1, Josephson junctions 201B to 201D corresponding to the Josephson junction 201A of the first qubit 20-1, superconducting members 204B to 204D corresponding to the superconducting members 204A of the first qubit 20-1, Josephson junctions 202B to 202D corresponding to the Josephson junction 202A of the first qubit 20-1, SQUIDs 210B to 210D corresponding to the SQUID 210A of the first qubit 20-1, and capacitors 206B to 206D corresponding to the capacitor 206A of the first qubit 20-1. Electrodes 24A and 24B of the first qubit 20-1 and the second qubit 20-2 are connected to a first electrode (first node) 17 of the coupler 21 via coupling capacitors 31A and 31B, and the electrodes 24C and 24D of the third qubit 20-3 and the fourth qubit 20-4 are connected to a second electrode (second node) 18 of the coupler 21 via coupling capacitors 31C and 31D.

The coupler 21 includes a SNAIL 221 and a capacitor 16 connected in parallel between the first electrode (first node) 17 and the second electrode 18 (second node). The SNAIL 221 includes a first Josephson junction 212-1, and the second Josephson junctions 213-1 and 213-2 connected in series. The number of the second Josephson junctions 213 connected in series is, as a matter of course, not limited to two.

When the first to fourth qubits 20-1 to 20-4 are configured to have the nonlinear parameters K₁ to K₄ with the same sign, and the coupler 21 is configured to have the nonlinear parameter K_{g} of the coupler 21 set opposite to signs of the nonlinear parameters K₁ to K₄ of the first to fourth qubits 20-1 to 20-4, values of (K₁+K_{g}), (K₂+K_{g}), (K₃+K_{g}), and (K₄+K_{g}) become small (if negative, absolute values), and the QC-CKI proportional to each thereof also becomes small.

When

$${K}_{1} = {K}_{2} = {K}_{3} = {K}_{4} = K > 0 , {K}_{g} = - K < 0 \qquad ( 7 )$$

or,

$${K}_{1} = {K}_{2} = {K}_{3} = {K}_{4} = K < 0 , {K}_{g} = - K > 0 \qquad ( 8 )$$

holds, the following holds.

$$( {K}_{1} + {K}_{g} ) = ( {K}_{2} + {K}_{g} ) = ( {K}_{3} + {K}_{g} ) = ( {K}_{4} + {K}_{g} ) = 0 \qquad ( 9 )$$

QC-CKI proportional to each thereof becomes 0.

The nonlinear parameters Kᵢ (i=1, 2, 3, 4) of the i-th qubit 20-i and the nonlinear parameter K_{g} of the coupler 21 can be broadly categorized into a component determined by an inductance and a component determined by a capacitance. For example, nonlinear parameter Kᵢ may be expressed by the following equation (10).

$${K}_{i} = {p}_{i} {E}_{C i} \qquad ( 10 )$$

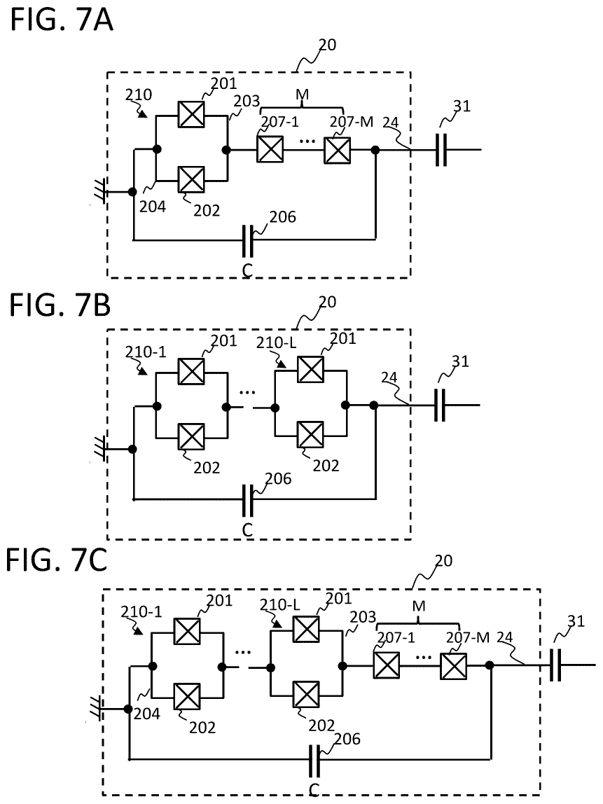

In equation (10),
pᵢ (Participation ratio) is a ratio of an inductive energy stored in the qubit (Josephson junction) to an inductive energy stored in the circuit, and may be given, for example, as follows.

$${p}_{i} = \frac{{n}_{i S} {L}_{iS}^{3} + {n}_{i J} {L}_{i J}^{3}}{{( {L}_{i L} + {n}_{i S} {L}_{i S} + {n}_{i J} {L}_{i J} )}^{3}} \qquad ( 11 )$$

where,
L_{iL} (i=1, 2, 3, 4) is a structural inductance of the i-th qubit 20-i,
L_{iS} (i=1, 2, 3, 4) is an inductance of a SQUID for the i-th qubit 20-i,
n_{iS} (i=1, 2, 3, 4) is the number of SQUIDs in the i-th qubit 20-i (FIG. 7B and FIG. 7C),
L_{iJ} (i=1, 2, 3, 4) is an inductance of a Josephson junction connected in series with the SQUID in the i-th qubit 20-i (FIG. 7A, FIG. 7C), and
n_{iJ} (i=1, 2, 3, 4) is the number of Josephson junctions (202-1-202-N in FIG. 3B) connected in series in the i-th qubit 20-i.

E_{Ci} in equation (10) may be given by the following equation (12).

$${E}_{C i} = \frac{{e}^{2}}{2 {C}_{i}} ( i = 1 , 2 , 3 , 4 ) \qquad ( 12 )$$

where e is the elementary charge, and Cᵢ is an effective structural capacitance of qubit 20.

For example, Cᵢ may be a capacitance of a capacitor 206 (shunt capacitor) of the i-th qubit 20-i.

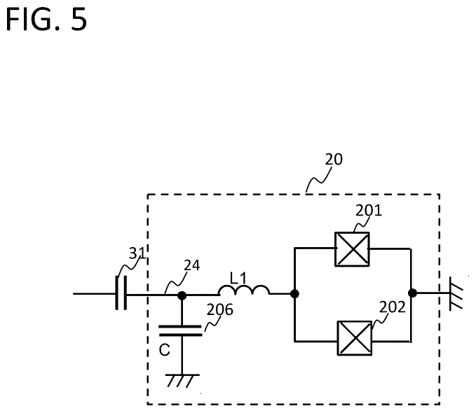

FIG. 5 illustrates a structural inductance of the SQUID 210 in the qubit 20. A maximum value of pᵢ (i=1, 2, 3, 4) in equation (11) is 1. To bring pᵢ closer to its maximum value, the structural inductance Lᵢ (inductance L1 in FIG. 5) needs to be reduced as much as possible.

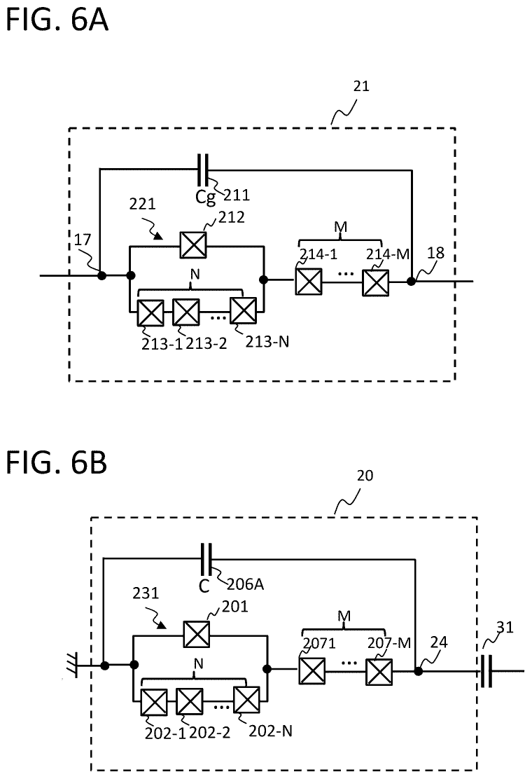

FIGS. 6A and 6B are diagrams illustrating variation examples of the circuit configurations in FIGS. 3A and 3B. Referring to FIG. 6A, in the coupler 21, a SNAIL 221 and M Josephson junctions 214 may be connected in series between the first electrode (first node) 17 and the second electrode (second node) 18. Referring to FIG. 6B, in the qubit 20, a SNAIL 231 and M (M≥1) Josephson junctions 207 may be connected in series between the electrode 24 and ground.

The configurations illustrated in FIGS. 7A, 7B, and 7C may also be used as configurations for varying the nonlinearity (Kerr nonlinearity) in the first to fourth qubits 20-1 to 20-4 of FIG. 4. FIG. 7A shows a configuration where the M Josephson junctions 207-1 to 207-M are connected in series with the SQUID 210 between the electrode 24 and ground. By changing the number M of the Josephson junctions 207-1 to 207-M, the nonlinearity (Kerr nonlinearity) of the qubit 20 can be altered. For example, increasing M reduces the nonlinearity. FIG. 7B shows a configuration where L SQUIDs 210-1 to 210-L are connected in series between the electrode 24 and ground. By changing the number L of the SQUIDs 210-1 to 210-L, the nonlinearity (Kerr nonlinearity) of the qubit 20 can be altered. As L increases, the nonlinearity decreases. FIG. 7C shows a configuration where the M Josephson junctions 207-1 to 207-M are connected in series with the L SQUIDs 210-1 to 210-L between the electrode 24 and ground. By changing the number L of the SQUIDs 210-1 to 210-L or the number M of the Josephson junctions 207-1 to 207-M, the nonlinearity (Kerr nonlinearity) of the qubit 20 can be altered. The coupler 21 may also be configured similarly. In this case, the ground and the electrode 24 in FIG. 7A, FIG. 7B, and FIG. 7C are replaced by the first electrode (first node) 17 and the second electrode (second node) 18 of the coupler 21.

The nonlinear parameter Kᵢ (i=1, . . . , 4) representing the nonlinearity (Kerr nonlinearity) of the i-th qubit 20-i using a SNAIL, may be expressed by equation (14), when a Hamiltonian Hᵢ of the qubit 20-i may be given by equation (13) (Reference Literature 1).

$${H}_{i} = {ω}_{i} {a}_{i}^{†} {a}_{i} + {{g}_{3 i} ( {a}_{i} + {a}_{i}^{†} )}^{3} + {{g}_{4 i} ( {a}_{i} + {a}_{i}^{†} )}^{4} , \qquad ( 13 )$$

In equation (13), ai⁺ and ai are creation and annihilation operators for bosons in the i-th qubit 20-i.

$${K}_{i} = 12 ( {g}_{4 i} - \frac{5 {g}_{3 i}^{2}}{{ω}_{i}} ) \qquad ( 14 )$$

where ωᵢ is the resonance angular frequency of the qubit 20-i.

Similarly, the parameter (Kerr coefficient) (nonlinear parameter) K_{g} representing the nonlinearity of the coupler 21 using a SNAIL may be expressed by the following equation (15).

$${K}_{g} = 12 ( {g}_{4 g} - \frac{5 {g}_{3 g}^{2}}{{ω}_{g}} ) \qquad ( 15 )$$

Where ω_{g} is the resonance angular frequency of the coupler 21.

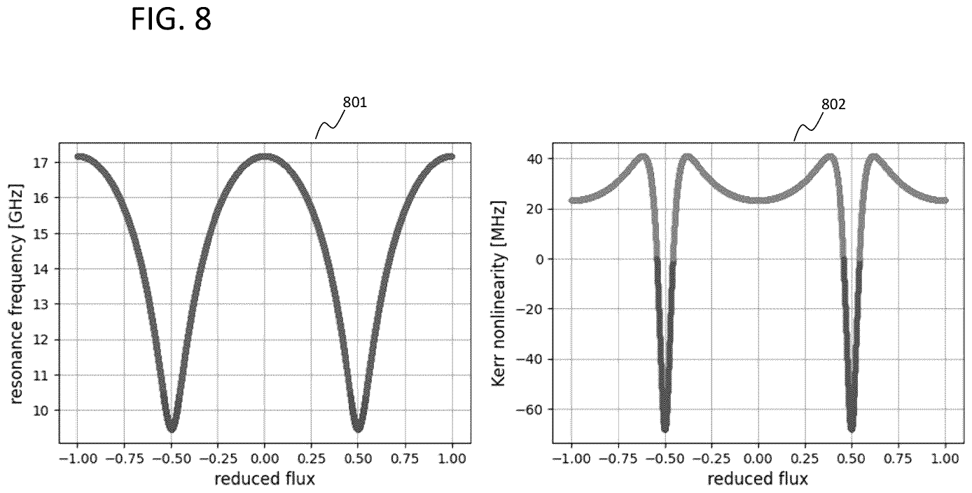

FIG. 8 shows an example of a magnetic field characteristic of the resonance frequency (GHz (Giga-Hertz)) (magnetic field response) 801 of a SNAIL and a magnetic field characteristic of the Kerr nonlinearity (MHz (Mega-Hertz)) (magnetic field response) 802 of a SNAIL. In graphs 801 and 802, the horizontal axis is a reduced flux (Φ/Φ₀, where Φ₀ is a magnetic flux quantum). For a JPO using a SNAIL with a negative nonlinear parameter, K becomes the minimum (locally minimum) when the magnitude of the applied magnetic flux is at a position where the resonance frequency of the JPO using the SNAIL (qubit) takes a minimum value (magnetic flux Φ=±0.5 Φ₀ (half-integer) (where Φ₀ is a magnetic flux quantum Φ₀=h/2e)). JPO using a SNAIL with a positive nonlinear parameter K operates outside the ±0.5 (half-integer) range of the applied magnetic flux (Φ=0.4 to −0.4 Φ₀, 0.6 to 1.4 Φ_{0, -0.6} to −1.4 Φ₀). Note that a SQUID cannot change the sign of the nonlinear parameter in the applied magnetic field.

When the nonlinear parameter K_{g} of the coupler 21 in FIG. 4 is set to a negative value, for example, with respect to the SNAIL 221 of the coupler 21, a magnetic field causing the nonlinear parameter K_{g} to become negative is applied from a magnetic field application section (not shown) to the magnetic field characteristic (magnetic field response) 802 of the Kerr nonlinearity illustrated in FIG. 8.

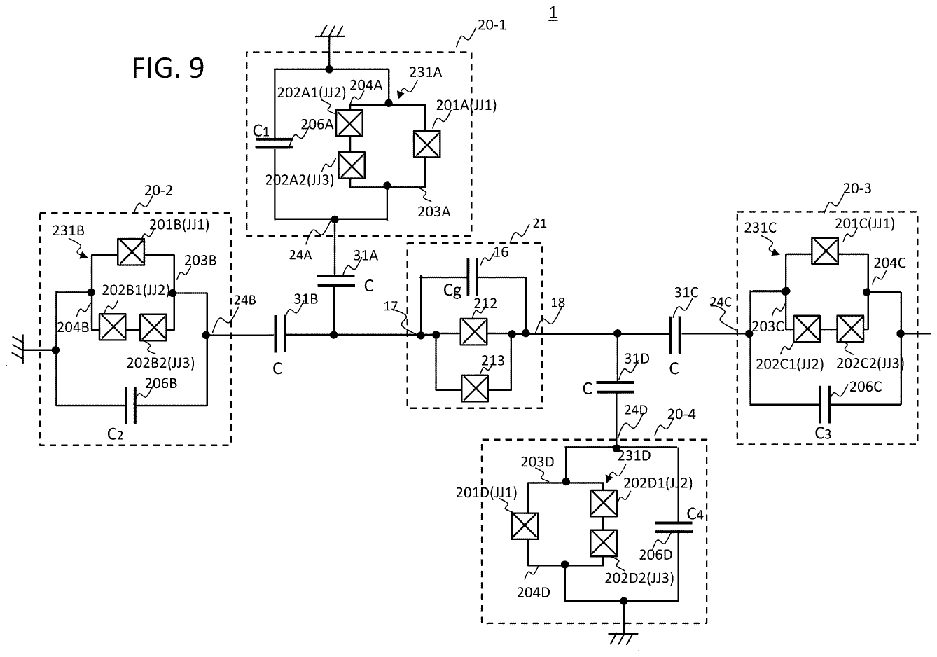

FIG. 9 is an example illustrating a variation example of FIG. 4 as an embodiment of the present disclosure. In the example of FIG. 9, the coupler 21 includes a SQUID (comprising Josephson junctions 212 and 213), and the first to fourth qubits 20-1 to 20-4 include SNAILS 231A to 231D. In the configuration of FIG. 9, for example, the sign of the nonlinear parameter K_{g} of the coupler 21 may be positive, the signs of the nonlinear parameters K₁ and K₄ of the first and fourth qubits 20-1 and 20-4 may be negative, and the signs of the nonlinear parameters K₂ and K₃ of the second and third qubits 20-2 and 20-3 may also be negative. In this case, a magnetic field (magnetic field response 802 in FIG. 8) for which the magnetic field characteristic 802 of the nonlinear parameter in FIG. 8 becomes negative is applied to the SNAIL 231A and 231D of the first and fourth qubits 20-1 and 20-4 from an unillustrated magnetic field application section. The first and fourth qubits (JPO) 20-1 and 20-4, including the SNAIL 231A and 231D, oscillate (parametric oscillation) due to the capacitively coupled AC signal. For example, an AC signal (at twice the resonance frequency) capacitively coupled to the electrodes 24A and 24D of the first qubit 20-1 and the fourth qubit 20-4, respectively, is supplied from a signal source (not shown). Meanwhile, magnetic fields (DC magnetic field+AC magnetic field (frequency approximately twice the resonance frequency)) are applied to the SQUIDs 210B and 210C of the second and third qubits 20-2 and 20-3, respectively, from unillustrated magnetic field application sections, causing them to oscillate (parametric oscillation) at a predetermined resonance frequency.

When the nonlinear parameters K₁ to K₄ of the first to fourth qubits 20-1 to 20-4 and the nonlinear parameter K_{g} of the coupler 21 are set as follows:

$${K}_{2} = {K}_{3} = K > 0 , {K}_{1} = {K}_{4} = - K < 0 , {K}_{g} = K > 0 \qquad ( 16 )$$

Among the six combinations of the sum of nonlinear parameters for two qubits 20 related to QQ-CKI, the following four combinations become zero.

$$( {K}_{1} + {K}_{2} ) = ( {K}_{1} + {K}_{3} ) = ( {K}_{2} + {K}_{4} ) = ( {K}_{3} + {K}_{4} ) = 0 \qquad ( 17 )$$

Additionally, among the four combinations of the sum of the nonlinear parameters of the coupler 21 and the qubits related to QC-CKI, the following two combinations become zero.

$$( {K}_{1} + {K}_{g} ) = ( {K}_{4} + {K}_{g} ) = 0 \qquad ( 18 )$$

Thus, according to the circuit of FIG. 9, QQ-CKI and QC-CKI can be suppressed. Note that equation (16) may also be expressed as:

$${K}_{2} = {K}_{3} = K < 0 , \qquad ( 19 )$$

$${K}_{1} = {K}_{4} = - K > 0 ,$$

$${K}_{g} = K > 0$$

In FIG. 9, when the resonant angular frequencies ω₁ to ω₄ of the first to fourth qubits 20-1 to 20-4 satisfy the following condition:

$${ω}_{1} + {ω}_{2} = {ω}_{3} + {ω}_{4} \qquad ( 20 )$$

the coupling strength (coefficient) h⁽⁴⁾ for the four-body interaction induced by nonlinearity of the first to fourth qubits 20-1 to 20-4 may be expressed by the following equation (21).

$${h}^{( 4 )} ≃ 2 {g}_{12} {g}_{13}^{2} \frac{( {K}_{2} - {K}_{1} ) {Δ}_{34} + ( {K}_{3} - {K}_{4} ) {Δ}_{12}}{{Δ}_{12} {Δ}_{13} {Δ}_{14} {Δ}_{34}} \qquad ( 21 )$$

In equation (21),
Kᵢ (i=1, 2, 3, 4) is a nonlinear parameter representing the nonlinearity of the qubit 20-i.

gᵢⱼ (i≠j=1, 2, 3, 4) represents the strength (magnitude) of the coupling between the i-th qubit 20-i and the j-th qubit 20-j.

Δᵢⱼ (i≠j=1, 2, 3, 4) represents the difference ωᵢ−ωⱼ between the resonance angular frequency ωᵢ of the i-th qubit 20-i and the resonance angular frequency ωⱼ of the j-th qubit 20-j.

That is, the coupling coefficient h⁽⁴⁾ of the four-body interaction arising from the nonlinearities between the qubits may be expressed (or approximated) as follows in equation (22).

$$\frac{{h}^{( 4 )}}{2} ≃ {\sum }_{i = 1}^{4} {\prod }_{{j = 1}_{( j ≏̸ i )}}^{4} ( \frac{{g}_{ij}}{{Δ}_{ji}} ) {K}_{i} \qquad ( 22 )$$

In equation (22), similar to equation (21), gᵢⱼ (i,j=1, 2, 3, 4 (j≠i)) represents the strength (magnitude) of the coupling between the j-th qubit 20-j and the i-th qubit 20-i (also called the “coupling constant”), while Δⱼᵢ (i,j=1, 2, 3, 4 (j≠i)) is the difference ωⱼ−ωᵢ between the resonance angular frequency ωⱼ of the j-th qubit 20-j and the resonance angular frequency ωᵢ of the i-th qubit 20-i. Kᵢ (i=1, 2, 3, 4) is the nonlinear parameter of the i-th qubit 20-i.

In equation (22), a multiplication term:

$${\prod }_{{j = 1}_{( j ≏̸ i )}}^{4} ( \frac{{g}_{ij}}{{Δ}_{ji}} ) {K}_{i}$$

may be expressed by the following equation (23), when gᵢⱼ (j=1, 2, 3, 4 (j≠i)) is denoted as g, Δⱼᵢ (j=1, 2, 3, 4 (j≠i)) as Δ, and K_{q} as the effective value including a sign of gᵢⱼ/Δⱼᵢ (an effective Kerr coefficient remaining after terms of signs±are cancelled out).

$${( \frac{g}{Δ} )}^{3} {K}_{q} \qquad ( 23 )$$

In equation (23), the following is assumed.

$$\frac{g}{Δ} < 1 \qquad ( 24 )$$

Under the above condition, making the difference Δ in the resonance angular frequency between two qubits (the i-th qubit 20-i and j-th qubit 20-j) as small as possible, may contribute to increasing a value of the equation (23).

From equation (23), increasing the nonlinearity parameter K_{q} of the qubit 20 also increases the coupling coefficient h⁽⁴⁾ of the four-body interaction. In equation (23), the nonlinearity parameter K_{q} of the qubit 20 is multiplied by the cubic term (g/Δ)³ of (g/Δ) (<1). Therefore, the coupling coefficient h⁽⁴⁾ for the four-body interaction due to the nonlinearity of the qubit 20 can be made relatively larger compared to g⁽⁴⁾ in equation (5) (the coupling coefficient for the four-body interaction among the four qubits 20 through the coupler 21). For example, when K_{q} and K_{g} are of the same order of magnitude, the coupling coefficient h⁽⁴⁾ can be nearly one order of magnitude larger than g⁽⁴⁾ in equation (5).

Expanding equation (22) for the first through fourth qubits 20-1 to 20-4 in FIG. 9, we have the following approximation equation (25).

$${h}^{( 4 )} ≃ 2 ( {K}_{1} \frac{{g}_{21}}{{Δ}_{21}} \frac{{g}_{31}}{{Δ}_{31}} \frac{{g}_{41}}{{Δ}_{41}} + {K}_{2} \frac{{g}_{12}}{{Δ}_{12}} \frac{{g}_{32}}{{Δ}_{32}} \frac{{g}_{42}}{{Δ}_{42}} + {K}_{3} \frac{{g}_{13}}{{Δ}_{13}} \frac{{g}_{23}}{{Δ}_{23}} \frac{{g}_{43}}{{Δ}_{43}} + {K}_{4} \frac{{g}_{14}}{{Δ}_{14}} \frac{{g}_{24}}{{Δ}_{24}} \frac{{g}_{34}}{{Δ}_{34}} ) \qquad ( 25 )$$

In equation (25), the condition for the first to fourth qubits 20-1 to 20-4 to be coupled via a four-body interaction (the condition concerning the resonance angular frequencies ω₁ to ω₄) may be defined as:

$${ω}_{1} + {ω}_{2} = {ω}_{3} + {ω}_{4} \qquad ( 26 )$$

From equation (26),

$${ω}_{3} - {ω}_{1} = - ( {ω}_{4} - {ω}_{2} )$$

$${ω}_{4} - {ω}_{1} = - ( {ω}_{3} - {ω}_{2} )$$

therefore,

$${Δ}_{13} = - {Δ}_{24} \qquad ( 27 )$$

$${Δ}_{14} = - {Δ}_{23} \qquad ( 28 )$$

Furthermore, regarding equation (25),
Δᵢⱼ (=ωᵢ−ωⱼ) is antisymmetric with respect to indices i and j:

$${Δ}_{ij} = - {Δ}_{ji} \qquad ( 29 )$$

gᵢⱼ is symmetric with respect to indices i and j:

$${g}_{ij} = {g}_{ji} \qquad ( 30 )$$

The coupling constant g₁₂ between the first and second qubits 20-1, 20-2 coupled to the first electrode 17 (first node) of the coupler 21 via the coupling capacitors 31A, 31B, and the coupling constant g₃₄ between the third and fourth qubits 20-3, 20-4 coupled to the second electrode 18 (second node) of the coupler 21 via coupling capacitors 31C, 31D, are approximated to be equal to each other when their mutual resonant angular frequencies are close.

$${g}_{12} = {g}_{34} \qquad ( 31 )$$

The coupling constant g₁₃ between the first and third qubits 20-1 and 20-3 coupled via the coupler 21, the coupling constant g₁₄ between the first and fourth qubits 20-1 and 20-4 coupled via the coupler 21, and the coupling constant g₂₃ between the second and third qubits 20-2 and 20-3 coupled via the coupler 21, and the coupling constant g₂₄ between the second and fourth qubits 20-2 and 20-4 coupled via the coupler 21 are approximated to be equal to each other when their respective resonance angular frequencies are close.

$${g}_{13} = {g}_{14} = {g}_{23} = {g}_{24} \qquad ( 32 )$$

Under equations (27) to (32), the above equation (25), from

$${h}^{( 4 )} ≃ 2 {g}_{12} {g}_{13}^{2} \{ {K}_{1} \frac{- 1}{{Δ}_{12} {Δ}_{13} {Δ}_{14}} + {K}_{2} \frac{1}{{Δ}_{12} {Δ}_{23} {Δ}_{24}} + {K}_{3} \frac{- 1}{{Δ}_{13} {Δ}_{23} {Δ}_{34}} + {K}_{4} \frac{1}{{Δ}_{14} {Δ}_{24} {Δ}_{34}} \} = - 2 {g}_{12} {g}_{13}^{2} ( {K}_{1} \frac{{Δ}_{34}}{{Δ}_{12} {Δ}_{13} {Δ}_{14} {Δ}_{34}} + {K}_{2} \frac{- {Δ}_{34}}{{Δ}_{12} {Δ}_{13} {Δ}_{14} {Δ}_{34}} + {K}_{3} \frac{- {Δ}_{12}}{{Δ}_{12} {Δ}_{13} {Δ}_{14} {Δ}_{34}} + {K}_{4} \frac{{Δ}_{12}}{{Δ}_{12} {Δ}_{13} {Δ}_{14} {Δ}_{34}} ) \qquad ( 33 )$$

may be expressed as the following equation (34).

$${h}^{( 4 )} ≃ 2 {g}_{12} {g}_{13}^{2} \frac{( {K}_{2} - {K}_{1} ) {Δ}_{34} + ( {K}_{3} - {K}_{4} ) {Δ}_{12}}{{Δ}_{12} {Δ}_{13} {Δ}_{14} {Δ}_{34}} \qquad ( 34 )$$

From equation (34), for example, if

$${K}_{1} = {K}_{4} = - K < 0 , {K}_{2} = {K}_{3} = K > 0 \qquad ( 35 a )$$

$$or$$

$${K}_{1} = {K}_{4} = - K > 0 , {K}_{2} = {K}_{3} = K < 0 , \qquad ( 35 b )$$

$$then$$

$$( {K}_{2} - {K}_{1} ) > 0 , ( {K}_{3} - {K}_{4} ) > 0 \qquad ( 36 a )$$

$$or$$

$$( {K}_{2} - {K}_{1} ) < 0 , ( {K}_{3} - {K}_{4} ) < 0. \qquad ( 36 b )$$

By setting the difference in resonance angular frequencies 434 and 412 to

$${Δ}_{34} > 0 , {Δ}_{12} > 0 \qquad ( 37 a )$$

$$or$$

$${Δ}_{34} < 0 , {Δ}_{12} < 0 , \qquad ( 37 b )$$

the value (absolute value if negative) of the numerator (K₂−K₁)Δ₃₄+(K₃−K₄)Δ₁₂ in equation (34) can be increased. Specifically, the coupling coefficient (strength) h⁽⁴⁾ of the four-body interaction due to the nonlinearity of the four qubits 20-1 to 20-4 can be increased. When using either equation (35a) or equation (35b), K₁+K₂=K₁+K₃=K₂+K₄=K₃+K₄=0, thereby suppressing QQ-CKI.

The coupling coefficient h⁽⁴⁾ (e.g., its absolute value) may be considered as the coupling strength of the four-body interaction that the coupling strength g⁽⁴⁾ (e.g., its absolute value) of the four-body between the qubits 20 via the coupler 21 in equation (5) is combined via addition or similar operations. Note that from equation (34), when K₁=K₂ and K₃=K₄, h⁽⁴⁾ becomes 0.

Furthermore, when the condition for the resonance angular frequencies ω₁ to ω₄ among the four qubits 20-1 to 20-4 is set as:

$${ω}_{1} + {ω}_{3} = {ω}_{2} + {ω}_{4} \qquad ( 38 )$$

then equation (25) may be expressed as the following equation (39).

$${h}^{( 4 )} = - 2 {g}_{12} {g}_{13}^{2} \frac{( {K}_{1} - {K}_{3} ) {Δ}_{24} + ( {K}_{4} - {K}_{2} ) {Δ}_{13}}{{Δ}_{12} {Δ}_{13} {Δ}_{14} {Δ}_{24}} \qquad ( 39 )$$

From equation (39), for example, if

$${K}_{1} = {K}_{4} = - K < 0 , {K}_{3} = {K}_{2} = K > 0 \qquad ( 40 a )$$

$$or$$

$${K}_{1} = {K}_{4} = - K > 0 , {K}_{2} = {K}_{3} = K < 0 , \qquad ( 40 b )$$

$$then$$

$$( {K}_{1} - {K}_{3} ) < 0 , ( {K}_{4} - {K}_{2} ) < 0 \qquad ( 41 a )$$

$$or$$

$$( {K}_{1} - {K}_{3} ) > 0 , ( {K}_{4} - {K}_{2} ) < 0. \qquad ( 41 b )$$

By setting the difference in resonance angular frequencies Δ₂₄ and Δ₁₃ to

$${Δ}_{24} < 0 , {Δ}_{13} < 0 \qquad ( 42 a )$$

$$or$$

$${Δ}_{24} > 0 , {Δ}_{13} > 0 , \qquad ( 42 b )$$

the value (absolute value if negative) of the numerator (K₁−K₃)Δ₂₄+(K₄−K₂)Δ₁₃ in equation (39) can be increased. Specifically, the coupling coefficient h⁽⁴⁾ of the four-body interaction due to the nonlinearity of the four qubits 20-1 to 20-4 can be increased. Furthermore, by setting the sign of the nonlinear parameter K_{g} of the coupler 21 to be opposite to either K₁ or K₂, at least part of the cross-Kerr interaction (QC-CKI) between the qubits 20 and the coupler 21 can be suppressed. Note that in equation (39), when K₁=K₃ and K₄=K₂, h⁽⁴⁾ becomes zero.

Furthermore, when the condition for the first to fourth qubits 20-1 to 20-4 to exhibit four-body interactions (the condition regarding the resonance angular frequencies ω₁ to ω₄) is set as

$${ω}_{1} + {ω}_{4} = {ω}_{2} + {ω}_{3} \qquad ( 43 )$$

then equation (25) may be expressed as the following equation (44).

$${h}^{( 4 )} = - 2 {g}_{12} {g}_{13}^{2} \frac{( {K}_{1} - {K}_{4} ) {Δ}_{23} + ( {K}_{3} - {K}_{2} ) {Δ}_{14}}{{Δ}_{12} {Δ}_{13} {Δ}_{14} {Δ}_{23}} \qquad ( 44 )$$

From equation (44), for example, if

$${K}_{1} = {K}_{3} = K > 0 , {K}_{2} = {K}_{4} = - K < 0 \qquad ( 45 a )$$

$$or$$

$${K}_{1} = {K}_{3} = K < 0 , {K}_{2} = {K}_{4} = - K > 0 , \qquad ( 45 b )$$

$$then$$

$$( {K}_{1} - {K}_{4} ) > 0 , ( {K}_{3} - {K}_{2} ) > 0 \qquad ( 46 a )$$

$$or$$

$$( {K}_{1} - {K}_{4} ) < 0 , ( {K}_{3} - {K}_{2} ) < 0. \qquad ( 46 b )$$

By setting the difference in resonance angular frequencies Δ₂₃ and Δ₁₄ to

$${Δ}_{23} > 0 , {Δ}_{14} > 0 \qquad ( 47 a )$$

$$or$$

$${Δ}_{23} < 0 , {Δ}_{14} < 0 , \qquad ( 47 b )$$

the value (absolute value if negative) of the numerator term in equation (44): (K₁−K₄)Δ₂₃+(K₃−K₂)Δ₁₄ can be increased. Specifically, the coupling coefficient h⁽⁴⁾ of the four-body interaction arising from the nonlinearity of the four qubits 20-1 to 20-4 can be increased.

Furthermore, equations (45a), (45b), (46a), and (46b) enable the suppression of a part of the QQ-CKI (four out of the six combinations involving the sum of nonlinear parameters of the two qubits 20). Furthermore, by setting the sign of the nonlinear parameter K_{g} of the coupler 21 to be opposite to either K₁ or K₂, which have opposite signs, it is possible to suppress a part of the QC-CKI (two out of the four combinations involving the sum of the nonlinear parameters of the qubit 20 and the coupler 21). Note that in equation (44), when K₁=K₄ and K₃=K₂, h⁽⁴⁾ becomes 0.

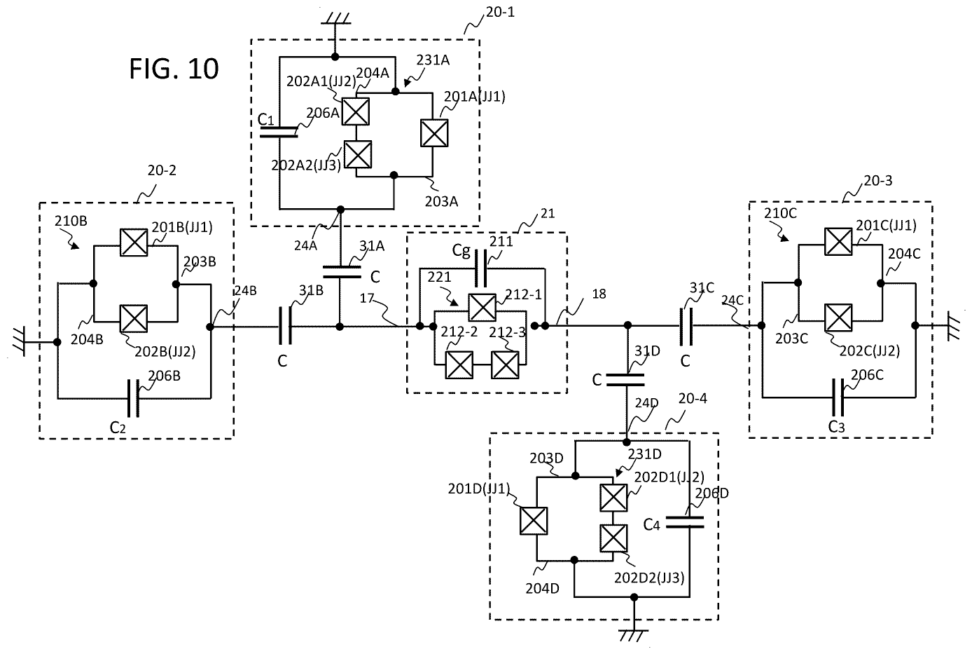

FIG. 10 illustrates an example of a further variation of FIG. 4, as one of embodiments of the present disclosure. In the example of FIG. 10, the coupler 21 includes a SNAIL 221 (including a parallel circuit of a Josephson junction 212-1 and serially connected Josephson junctions 212-2 and 212-3). The first qubit 20-1 and the fourth qubit 20-4 include SNAILS 231A and 231D, respectively. The second qubit 20-2 and the third qubit 20-3 include SQUIDs 210B and 210C, respectively.

The first and fourth qubits (JPO) 20-1 and 20-4, including SNAILS 231A and 231D, oscillate (parametrically oscillate) due to AC signals applied thereto respectively by capacitively coupling. For example, the AC signals (at twice the resonance frequency of each of the first and fourth qubits (JPO) 20-1 and 20-4) may be applied by capacitive coupling to the electrodes 24A and 24D of the first qubit 20-1 and the fourth qubit 20-4, respectively, are supplied from signal sources (not shown). Magnetic fields (DC magnetic field+AC magnetic field (frequency approximately twice the resonance frequency of each of the second and third qubits 20-2 and 20-3) are applied to the SQUIDs 210B and 210C of the second and third qubits 20-2 and 20-3, respectively, from magnetic field application parts (not shown), causing each of the second and third qubits 20-2 and 20-3 to oscillate (parametrically oscillate) at a predetermined resonance frequency. The coupler 21, including the SNAIL 221, oscillates due to AC signal capacitively coupled to the electrodes of the SNAIL 221, for example. The first and fourth qubits (JPO) 20-1 and 20-4, including the SNAILS 231A and 231D, and the coupler 21 including the SNAIL 221, have respectively magnetic fields according to the magnetic field characteristic (magnetic field response) 802 as illustrated in FIG. 8, applied thereto, thereby the sign (positive or negative) of the nonlinear parameter thereof being determined. In the configuration of FIG. 10, the sign of the nonlinear parameter K_{g} of the coupler 21 may be set to negative (−K), the nonlinear parameters K₁ and K₄ of the first qubit 20-1 and the fourth qubit 20-4 may be set to negative (−K), and the nonlinear parameters K₂ and K₃ of the second qubit 20-2 and the third qubit 20-3 may be set to positive (+K) Alternatively, the opposite may also be applied.

In this case, the QC-CKI values proportional to (K₂+K_{g}) and (K₃+K_{g}) are both zero, while QC-CKI values proportional to (K₁+K_{g}) and (K₄+K_{g}) remain.

The QQ-CKI values proportional to (K₁+K₂), (K₁+K₃), (K₂+K₄), and (K₃+K₄) respectively, are zero in all cases. While the QQ-CKI values proportional to (K₁+K₄) and (K₂+K₃) remain. It is possible to suppress two out of the four QC-CKI and four out of the six QQ-CKI. For simplicity, the nonlinear parameter K_{g} of the coupler 21 is set to a negative value (−K, K>0), the nonlinear parameters K₁ and K₄ of the first qubit 20-1 and the fourth qubit 20-4 are set to negative values (−K), and the nonlinear parameters K₂ and K₃ of the second qubit 20-2 and the third qubit 20-3 are set to positive values (+K). However, a combination of values (signs) for the nonlinear parameters may be any arbitrary combination.

In FIG. 10, the first qubit 20-1 to the fourth qubit 20-4, and the coupler 21, may each be configured using a JPO equipped with a SNAIL.

Even in the configuration of FIG. 10, the coupling strength of the four-body interaction (coupling coefficient) h⁽⁴⁾, expressed by the above equations (34), (39), (44), etc., can also be realized.

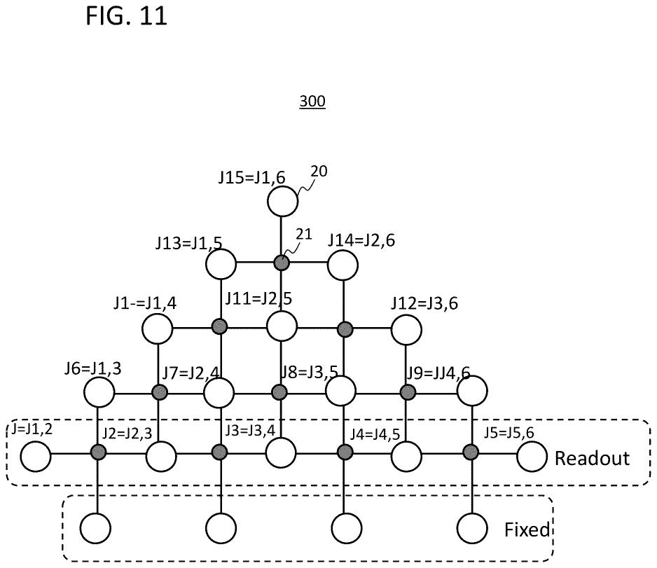

FIG. 11 is a diagram illustrating the configuration of a quantum computing apparatus (quantum annealing machine) 300, which includes the four qubits 20-1 to 20-4 and the coupler 21 described above as a unit (plaquette). In FIG. 11, the gray circle represents the coupler 21, and the four white circles surrounding it represent the qubits 20, which are physical qubits.

A Hamiltonian for all-to-all Ising spin glass model may be given by the following equation (48).

$${H}_{f} = {\sum }_{i = 1}^{N - 1} {\sum }_{i < j}^{N} {J}_{i j} {σ}_{Z}^{( i )} {σ}_{Z}^{0 )} + {\sum }_{i = 1}^{N} {b}_{i} {σ}_{Z}^{( i )} \qquad ( 48 )$$

where σ⁽ⁱ⁾_{Z} is a spin operator (Pauli matrix z-component), Jᵢⱼ is an interaction coefficient, and
bᵢ is a local magnetic field.

Equation (48) may be expanded to a physical qubit Hamiltonian given by the following equation (49), with K=N(N−1)/2 (for N=6, K=15).

$${H}_{p} = {\sum }_{k = 1}^{K} {J}_{k} {\tilde{σ}}_{Z}^{( k )} + {\sum }_{l = 1}^{K - N + 1} {C}_{l} = {\sum }_{k = 1}^{K} {J}_{k} {\tilde{σ}}_{Z}^{( k )} - ( C {\sum }_{l = 1}^{K - N + 1} {{\tilde{σ}}_{z}}^{( l , n )} {{\tilde{σ}}_{z}}^{( l , e )} {{\tilde{σ}}_{z}}^{( l , s )} {{\tilde{σ}}_{z}}^{( l , w )} ) \qquad ( 49 )$$

The interaction coefficient (matrix) Jᵢⱼ of the fully connected Ising spins in equation (48) is transformed to a local magnetic field Jₖ acting on a physical qubit in the Hamiltonian of equation (49). C₁ in equation (49) is a constraint (see NPL 1). In equation (49),

$${\tilde{σ}}_{z}^{( k )}$$

is a kth physical spin (Pauli matrix z component). C₁ (1∈{1, . . . , K−N+1}) in equation (49) are constructed from conditions on closed loops of logical qubits with necessary requirements (i) that the constraints cover all physical qubits and (ii) that the number of constraints is at least K−N. An example of a four-body interaction is illustrated. Note that (1, n), (1, e), (1, s), (1, w) represent the 1-th plaquette (a region enclosed by four physical qubits connected to common node n1), where n, e, s, w denote the four physical qubits located east, west, south, and north relative to node n1. For the configuration in FIG. 11, the total number of constraints in equation (49) is K−N+1=15-6+1=10, consisting of the sum of constraints C₁ to C₁₀. Nine distinct frequencies are assigned to prevent an occurrence of an extra four-body interaction, and the numbers 1 to 9 within each circle (physical qubit) represent labels for the nine different frequencies. The bottom row of four qubits holds fixed values, and a solution to the optimization problem is read out from the row one above the bottom.

In the present disclosure, the quantum circuit apparatus may be integrated as a chip. In this case, the substrate may be silicon (Si), for example, but other electronic materials such as sapphire or compound semiconductor materials (Group IV, Group III-V, Group II-VI) may also be used. Furthermore, while a single-crystal substrate is preferable for quantum chips, polycrystalline or amorphous substrates may also be used. The wiring layer patterns on quantum chips may be formed b y depositing (vapor-depositing) a superconducting material onto the substrate surface and then patterning it. For superconducting materials (interconnect materials) used in interconnects and electrodes within the interconnect layer of quantum chips, materials such as Nb (niobium) or Al (aluminum) are used. However, these are not limited to these materials; niobium nitride, indium (In), lead (Pb), tin (Sn), rhenium (Re), palladium (Pd), titanium (Ti), titanium nitride, molybdenum (Mo), tantalum (Ta), tantalum nitride, and alloys containing at least one of these, or any other metal that enters a superconducting state when cooled to cryogenic temperatures. There are no particular limitations, but as a Josephson junction, a first aluminum film may be formed on the surface of the quantum chip substrate by oblique epitaxy, oxidized to form a tunnel oxide film (AlOₓ), and a second aluminum film may be formed by oblique epitaxy from the opposite direction to the previous one, thereby forming a Josephson junction (Al/AlOₓ/Al).

While SQUIDs and SNAILs are used as examples of nonlinear elements for qubits 20 and a coupler 21, ATS (Asymmetrically Threaded SQUID) or STS (Symmetrically Threaded SQUID) may also be used Other configuration of Josephson junctions may be possible. For example, a qubit 20 may also include a transmon formed by a Josephson junction and a capacitor.

Cross-Kerr nonlinear interaction described above is not limited to that in superconducting quantum circuits, but is applicable to cross-Kerr nonlinear interaction between an optical cavity and a microwave. That is, while the JPO is used as an example to describe a Kerr parametric oscillator (KPO) exhibiting a Kerr effect, it goes without saying that the qubits 20-1 to 20-4 could also be implemented using a KPO other than a JPO.

### REFERENCE LITERATURE 1

Timo Hillmann, Fernando Quijandria, “Designing Kerr Interactions for Information Processing via Counterrotating Terms of Asymmetric Josephson-Junction Loops”, Phys. Rev. Applied 17, 064018—Published 9 Jun. 2022

The above embodiments/examples may be listed as the following supplementary notes (Note), though not limited thereto.

(Note 1) A quantum circuit apparatus of the present disclosure, a quantum circuit apparatus includes N qubits, where Nis a predetermined integer of 3 or greater; and a coupler, the N qubits configured to be coupled through the coupler via a many-body interaction, wherein at least one qubit of the N qubits is configured to have a sign of a parameter representing nonlinearity of the at least one qubit different from a sign of a parameter representing nonlinearity of the coupler and/or a sign of a parameter representing nonlinearity of at least one other of the N qubits.

(Note 2) In the quantum circuit apparatus according to Note 1, the many-body interaction is a four-body interaction of four qubits, where the N is set to 4.

(Note 3) In the quantum circuit apparatus according to Note 1 or 2, the coupler includes at least one of: a Josephson junction; a SQUID (Superconducting Quantum Interference Device) with a plurality of Josephson junctions arranged i n a loop; a n d a SNAIL (Superconducting Nonlinear Asymmetric Inductive eLement) including a loop in which at least one Josephson junction and a plurality of Josephson junctions connected in series are arranged in parallel.

(Note 4) In the quantum circuit apparatus according to any one of Notes 1 to 3, the qubit includes at least one of: a Josephson junction; a SQUID (Superconducting Quantum Interference Device) with a plurality of Josephson junctions arranged in a loop; and a SNAIL (Superconducting Nonlinear Asymmetric Inductive eLement) including a loop in which at least one Josephson junction and a plurality of Josephson junctions connected in series are arranged in parallel.

(Note 5) In the quantum circuit apparatus according to any one of Notes 1 to 4, the qubits capacitively couple to the coupler.

(Note 6) In the quantum circuit apparatus according to Note 2, a combined value of a coupling coefficient h⁽⁴⁾ for the four-body interaction due to nonlinearity of the four qubits and a coupling coefficient g⁽⁴⁾ for the four-body interaction among the four qubits through the coupler corresponds to a strength of the four-body interaction.

(Note 7) In the quantum circuit apparatus according to any one of Notes 1 to 6, at least one pair of qubits out of the N qubits are configured to have positive and negative parameters, each representing the nonlinearity of each of the at least one pair of qubits, respectively, to suppress or cancel out a cross-Kerr interaction (QQ-CKI) acting between the at least one pair of qubits.

(Note 8) In the quantum circuit apparatus according to any one of Notes 1 to 7, at least a qubit out of the N qubits and the coupler are configured to have different signs of parameters, each representing the nonlinearity of each of the qubit and the coupler, to suppress or cancel out a cross-Kerr interaction (QC-CKI) acting between the at least a qubit and the coupler.

(Note 9) In the quantum circuit apparatus according to any one of Notes 1 to 8, a plurality of basic units (plaquettes), each including the four qubits and the coupler are arranged to construct a quantum computer.

(Note 10) A control method of a quantum circuit that includes N qubits, where Nis a predetermined integer of 3 or greater; and a coupler, the N qubits configured to be coupled through the coupler via a many-body interaction, the method including configuring at least one qubit of the N qubits to have a sign of a parameter representing nonlinearity of the at least one qubit different from a sign of a parameter representing nonlinearity of the coupler and/or a sign of a parameter representing nonlinearity of at least one other of the N qubits.

(Note 11) In the method according to Note 10, the many-body interaction is four-body interaction of four qubits, where the Nis set to 4.

(Note 12) In the method according to Note 10 or 11, at least one pair of qubits out of the N qubits are configured to have positive and negative parameters, each representing the nonlinearity of each of the at least one pair of qubits, respectively, to suppress or cancel out a cross-Kerr interaction (QQ-CKI) acting between the at least one pair of qubits.

(Note 13) In the method according to any one of Notes 10 to 12, at least a qubit out of the N qubits and the coupler are configured to have different signs of parameters, each representing the nonlinearity of each of the qubit and the coupler, to suppress or cancel out a cross-Kerr interaction (QC-CKI) acting between the at least a qubit and the coupler.

The disclosures of each of the above-described documents are hereby incorporated by reference into this document. Within the scope of the disclosure of the present application (including the claims), modifications, adjustments, and combinations of embodiments or examples based on the fundamental technical concept are possible. Furthermore, within the scope of the claims of the present disclosure, various combinations or selections of the disclosed elements (including each element of the appended claims, each element of the embodiments, each element of the drawings, etc.) are possible. That is, the present disclosure naturally encompasses the entire disclosure, including the claims, and various modifications and alterations that would be obvious to one skilled in the art based on the technical concept.

What is claimed is:

1. A quantum circuit apparatus comprising:
N qubits, where N is a predetermined integer of 3 or greater; and
a coupler, the N qubits configured to be coupled through the coupler via a many-body interaction,
wherein at least one qubit of the N qubits is configured to have a sign of a parameter representing nonlinearity of the at least one qubit different from a sign of a parameter representing nonlinearity of the coupler and/or a sign of a parameter representing nonlinearity of at least one other of the N qubits.

2. The quantum circuit apparatus according to claim 1, wherein the N is 4 and the many-body interaction is a four-body interaction of four qubits.

3. The quantum circuit apparatus according to claim 2, wherein the coupler includes at least one of:
a Josephson junction;
a SQUID (Superconducting Quantum Interference Device) with a plurality of Josephson junctions arranged in a loop; and
a SNAIL (Superconducting Nonlinear Asymmetric Inductive element) including a loop in which at least one Josephson junction and a plurality of Josephson junctions connected in series are arranged in parallel.

4. The quantum circuit apparatus according to claim 1, wherein the qubit includes at least one of:
a Josephson junction;
a SQUID (Superconducting Quantum Interference Device) with a plurality of Josephson junctions arranged in a loop; and
a SNAIL (Superconducting Nonlinear Asymmetric Inductive eLement) including a loop in which at least one Josephson junction is connected in parallel to a plurality of Josephson junctions connected in series.

5. The quantum circuit apparatus according to claim 1, wherein the N qubits are capacitively coupled to the coupler, respectively.

6. The quantum circuit apparatus according to claim 2, wherein a combined value of a coupling coefficient h⁽⁴⁾ for the four-body interaction due to nonlinearity of the four qubits and a coupling coefficient g⁽⁴⁾ for the four-body interaction among the four qubits through the coupler corresponds to a strength of the four-body interaction.

7. The quantum circuit apparatus according to claim 1, wherein at least one pair of qubits out of the N qubits are configured to have positive and negative parameters, each representing the nonlinearity of each of the at least one pair of qubits, respectively, to suppress or cancel out a cross-Kerr interaction (QQ-CKI) acting between the at least one pair of qubits.

8. The quantum circuit apparatus according to claim 1, wherein at least a qubit out of the N qubits and the coupler are configured to have different signs of parameters, each representing the nonlinearity of each of the at least a qubit and the coupler, to suppress or cancel out a cross-Kerr interaction (QC-CKI) acting between the at least a qubit and the coupler.

9. The quantum circuit apparatus according to claim 2, wherein the four qubits and the coupler constitute a basic unit, wherein the quantum circuit apparatus includes a plurality of the basic units arranged to construct a quantum computer.

10. The quantum circuit apparatus according to claim 1, wherein the nonlinearity is Kerr-nonlinearity of the qubit.

11. A control method of a quantum circuit that includes N qubits, where N is a predetermined integer of 3 or greater; and a coupler, the N qubits configured to be coupled through the coupler via a many-body interaction, the method comprising
configuring at least one qubit of the N qubits to have a sign of a parameter representing nonlinearity thereof different from
a sign of a parameter representing nonlinearity of the coupler and/or
a sign of a parameter representing nonlinearity of at least one other of the N qubits.

12. The method according to claim 11, wherein the N is 4 and the many-body interaction is a four-body interaction of four qubits.

13. The method according to claim 11, comprising:
configuring at least one pair of qubits out of the N qubits to have positive and negative parameters, each representing the nonlinearity of each of the at least one pair of qubits, respectively, to suppress or cancel out a cross-Kerr interaction (QQ-CKI) acting between the at least one pair of qubits.

14. The method according to claim 11, comprising:
configuring at least a qubit out of the N qubits and the coupler to have different signs of parameters, each representing the nonlinearity of each of the qubit and the coupler, to suppress or cancel out a cross-Kerr interaction (QC-CKI) acting between the at least a qubit and the coupler.

15. The method according to claim 11, wherein the nonlinearity is Kerr-nonlinearity of the qubit.
